(19) United States
(12) Patent Application Publication
(10) Pub. No.: US 2026/0045942 A1
(43) Pub. Date: Feb. 12, 2026

(54) LATCH COMPARATOR

(71) Applicants: Infineon Technologies AG, Neubiberg (DE); Politecnico Di Milano, Milan (IT)

(72) Inventors: Andrea Cristofoli, Villach (AT); Michele Rocco, Martignacco (IT); Luca Bertulessi, Monza (IT)

(21) Appl. No.: 18/798,277

(22) Filed: Aug. 8, 2024

(51) Int. Cl. H03K 5/24; H03M 1/46

(52) U.S. Cl. CPC H03K 5/2481; H03M 1/462; H03M 1/468

(57) ABSTRACT

A latch comparator is disclosed. The latch comparator includes a first reservoir capacitor; a preamplifier including first and second transistors respectively connected to first and second inputs, the first and second transistors selectably connectable to a first terminal of the first reservoir capacitor, and third and fourth transistors respectively connected to the first and second inputs, the third and fourth transistors selectably connectable to a second terminal of the first reservoir capacitor; and a latch, including a first portion serially connected between the first and third transistors and connected to a first output, and a second portion serially connected between the second and fourth transistors and connected to a second output.

### TECHNICAL FIELD

The present invention relates generally to comparator circuits, and, in particular embodiments, to strong-arm latch comparators.

### BACKGROUND

Conventional dynamic comparator architectures show a high sensitivity to the applied input common-mode voltage which heavily influences the comparator performance. For example, the input-referred noise and offset, the energy per comparison, and the decision time may be adversely affected because of the sensitivity to the input common-mode.

This problem may affect a Successive-Approximation Register (SAR) Analog-to-Digital Converter (ADCs) that employs a dynamic comparator to generate the bits of the digital output code. Depending on the switching scheme of the Capacitive DAC (CDAC), during the conversion, the comparator input undergoes several voltage variations in the differential mode as well in the common mode. Therefore, common-mode voltage variations need to be carefully considered during the comparator design, dealing with a more complex circuit implementation of the comparator itself and/or of the overall ADC to avoid degradation of performance parameters such as SNR and linearity.

### SUMMARY

A first embodiment is a latch comparator, including a first reservoir capacitor; a preamplifier including first and second transistors respectively connected to first and second inputs, the first and second transistors selectably connectable to a first terminal of the first reservoir capacitor, and third and fourth transistors respectively connected to the first and second inputs, the third and fourth transistors selectably connectable to a second terminal of the first reservoir capacitor; and a latch, including a first portion serially connected between the first and third transistors and connected to a first output, and a second portion serially connected between the second and fourth transistors and connected to a second output.

Another embodiment is a data converter, including the latch comparator of the first embodiment; a sample and hold circuit connected to the first and second inputs of the latch comparator; a capacitive digital to analog converter (DAC) connected to the sample and hold circuit; and a successive approximation register (SAR) logic circuit connected to the capacitive DAC and to the first and second outputs of the latch comparator.

Another embodiment is a latch comparator, including a reservoir capacitor; first and second transistors respectively connected to first and second inputs, the first and second transistors selectably connectable to a first terminal of the reservoir capacitor; third and fourth transistors respectively connected to the first and second inputs, the third and fourth transistors selectably connectable to a second terminal of the reservoir capacitor; fifth and sixth transistors serially connected between the first and third transistors and connected to a first output; and seventh and eighth transistors serially connected between the second and fourth transistors and connected to a second output.

Another embodiment is a method of operating a latch comparator, the method including during a reset phase, charging a reservoir capacitor to a first voltage; and during an comparison phase, connecting the reservoir capacitor to first, second, third, and fourth transistors, where the first, second, third, and fourth transistors, and a latch are configured to float during the comparison phase, and where at least one of the first transistor is configured to provide current to the third transistor through the latch, where the latch generates a differential output voltage, or the second transistor is configured to provide current to the fourth transistor through the latch, where the latch generates a differential output voltage.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a schematic circuit diagram of an exemplary successive-approximation register (SAR) Analog-to-Digital Converter (ADC) according to some embodiments;

FIG. 2 is a schematic circuit diagram of a latch comparator according to some embodiments;

FIG. 3 is a schematic circuit diagram of a latch comparator in a reset phase according to some embodiments;

FIG. 4 is a schematic circuit diagram of a latch comparator in an integration phase according to some embodiments;

FIG. 5 is a schematic circuit diagram of a latch comparator in a propagation phase according to some embodiments;

FIG. 6 is a schematic circuit diagram of a latch comparator in a regeneration phase according to some embodiments;

FIG. 7 is a schematic circuit diagram of a latch comparator according to some embodiments; and

FIG. 8 is a flowchart of a method according to some embodiments.

FIG. 9 is a flowchart of a method of operating a latch comparator according to some embodiments.

### DETAILED DESCRIPTION OF ILLUSTRATIVE EMBODIMENTS

Illustrative embodiments of the system and method of the present disclosure are described below. In the interest of clarity, all features of an actual implementation may not be described in this specification. It will of course be appreciated that in the development of any such actual embodiment, numerous implementation-specific decisions may be made to achieve the developer's specific goals, such as compliance with system-related and business-related constraints, which will vary from one implementation to another. Moreover, it should be appreciated that such a development effort might be complex and time-consuming but would nevertheless be a routine undertaking for those of ordinary skill in the art having the benefit of this disclosure.

Some embodiments of the present disclosure provide a single-stage comparator architecture that avoids an interface between stages found in conventional two-stage comparator designs. By using a single-stage architecture, these embodiments can eliminate the need to slow down the latching circuit or include delay elements, thereby reducing unwanted delays, complexity, and size compared to two-stage comparators.

Certain embodiments also incorporate a self-quenching mechanism that automatically stops the reservoir capacitor discharge. This can obviate the need for a separate logic element to open switches after latch regeneration, which is used in some conventional circuits to cut off current from the reservoir capacitor to save power and speed up recharging.

In some embodiments, a single-stage floating inverter amplifier (FIA) comparator with an embedded latch is used, which may be insensitive to input common-mode voltage variations. Compared to conventional FIA-based comparator architectures, embodiments of the present disclosure can be simpler by avoiding an interface between a pre-amplifier and latch. Additionally, some embodiments do not use or need a logic gate to open the reservoir capacitor switches due to the incorporated self-quenching mechanism that automatically stops the reservoir capacitor discharge.

In contrast to conventional FIA-based topologies, some embodiments include a one-stage comparator which stops drawing charge from a floating reservoir capacitor by transitioning to the comparator output state and, therefore, does not use logic elements to stop the discharge of the reservoir capacitor.

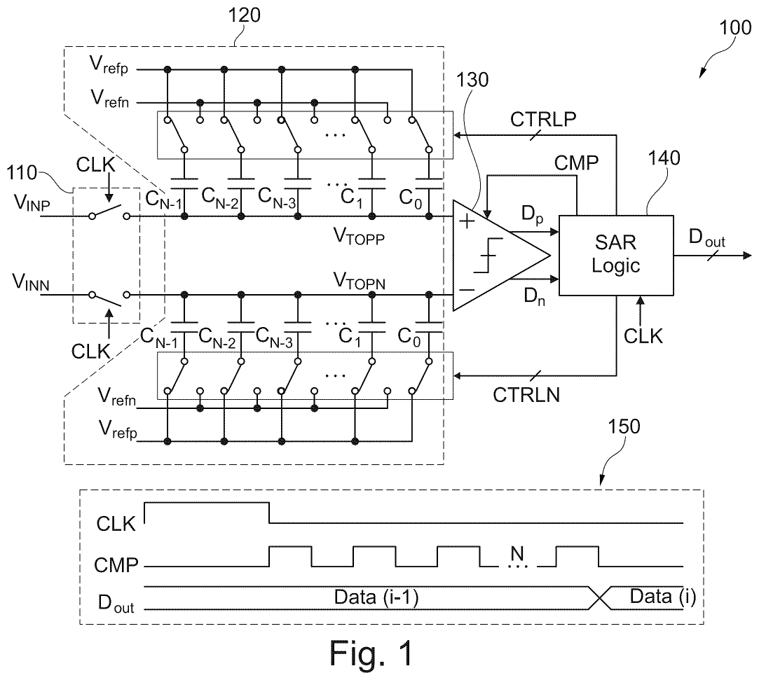

FIG. 1 is a schematic circuit diagram of a successive-approximation register (SAR) Analog-to-Digital Converter (ADC) 100 according to some embodiments. SAR ADC 100 includes sample and hold switches 110, capacitive digital-to-analog converter (DAC) 120, latch comparator 130, and SAR logic 140. SAR ADC 100 is an example of a circuit using a comparator having features similar or identical to those discussed with reference to the embodiments disclosed herein. Other circuits may use comparators having features similar or identical to those discussed with reference to the embodiments disclosed herein.

Sample and hold switches 110 selectively connect input nodes vinp and vinn with comparator input nodes Vtopp and Vtopn, respectively, according to clock signal CLK. While the sample and hold switches 110 are closed, charge corresponding with a differential input voltage across input nodes vinp and vinn is stored on the capacitors of capacitive DAC 120.

While the sample and hold switches 110 are open, capacitive DAC 120 is configured to provide a sequence of differential input voltages to latch comparator 130 according to control signals CTRLP and CTRLN from SAR logic 140. In addition, while the sample and hold switches 110 are open, latch comparator 130 is configured to generate a sequence of comparator outputs corresponding with the sequence of differential input voltages received from capacitive DAC 120. Latch comparator 130 is configured to generate the sequence of comparator outputs according to a comparator signal CMP from SAR logic 140.

SAR logic 140 is configured to generate the control signals CTRLP and CTRLN and the comparator signal CMP so that the sequence of the comparator outputs corresponds with a digital representation of the differential input voltage across input nodes vinp and vinn according to a successive approximation control algorithm. In addition, SAR logic 140 is configured to receive the sequence of comparator outputs and to generate a digital output code Dout based on the sequence of comparator outputs, where the digital output code Dout corresponds with a digital representation of the differential input voltage across input nodes vinp and vinn sampled with sample and hold switches 110.

In some embodiments, latch comparator 130 is a single-stage floating inverter amplifier (FIA) comparator with an embedded latch. In some embodiments, latch comparator 130 is substantially insensitive to input common-mode voltage variations.

Timing diagram 150 illustrates an example of relative timing between clock signal CLK, comparator signal CMP, and digital output code Dout according to some embodiments.

The high portion of clock signal CLK causes sample and hold switches 110 to be closed. While the sample and hold switches 110 are closed, the differential input voltage is stored on the capacitors of capacitive DAC 120.

The low portion of clock signal CLK causes sample and hold switches 110 to be open, and causes SAR logic 140 to generate control signals CTRLP and CTRLN. In addition, control signals CTRLP and CTRLN cause capacitive DAC 120 to provide a sequence of differential input voltages to latch comparator 130. In addition, the low portion of clock signal CLK causes SAR logic 140 to generate comparator signal CMP, and each cycle of comparator signal CMP causes latch comparator 130 to generate a next comparator output based on a current differential input voltage from capacitive DAC 120. Accordingly, latch comparator 130 generates a sequence of comparator outputs corresponding with the sequence of differential input voltages received from capacitive DAC 120. Once a last comparator output of the sequence is received by SAR logic 140, SAR logic 140 is configured to generate the digital output code Dout, where the digital output code Dout corresponds with a digital representation of the differential input voltage across input nodes vinp and vinn sampled with sample and hold switches 110. In some embodiments, the number of bits of the digital output code Dout corresponds with the number of cycles of comparator signal CMP.

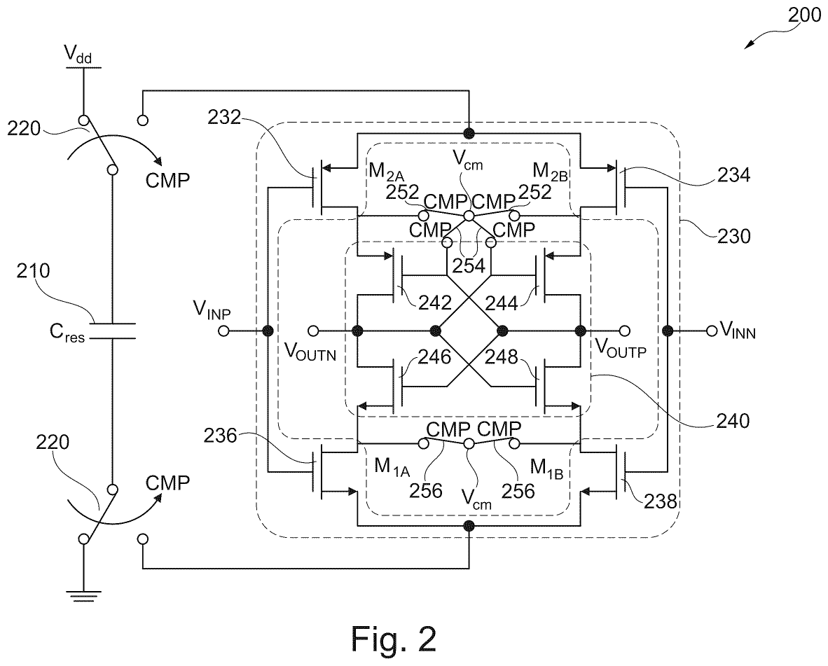

FIG. 2 is a schematic circuit diagram of a latch comparator 200 according to some embodiments. Latch comparator 200 may be used, for example, as latch comparator 130 in SAR ADC 100. In some embodiments, comparators having features similar or identical to latch comparator 200 may be used as latch comparator 130 and SAR ADC 100. In some embodiments, latch comparator 200 or a comparator having features similar or identical to latch comparator 200 may be used in other SAR ADC circuits, or in other circuits.

Latch comparator 200 includes reservoir capacitor 210, reservoir capacitor switches 220, preamplifier 230, latch 240, and reset switches 252, 254, and 256.

Reservoir capacitor 210 is configured to be selectively connected across power supply voltages Vdd and ground by reservoir capacitor switches 220 according to a comparator signal CMP. While reservoir capacitor 210 is connected to power supply voltages Vdd and ground, during a reset phase, reservoir capacitor 210 is charged to power supply voltage Vdd.

Reservoir capacitor 210 is also configured to be selectively connected across preamplifier 230 by reservoir capacitor switches 220 according to the comparator signal CMP. While reservoir capacitor 210 is connected across preamplifier 230, during a comparison phase, reservoir capacitor 210 is discharged or partially discharged through preamplifier 230 and latch 240.

Reset switches 252, 254, and 256 are configured to selectively connect various nodes of preamplifier 230 and latch 240 to a reset voltage Vcm, as illustrated. Reset switches 252, 254, and 256 selectively connect and disconnect the nodes of preamplifier 230 and latch 240 to the reset voltage according to comparator signal CMP. The comparator signal CMP causes reservoir capacitor 210 to be connected to the power supply voltages Vdd and ground during the reset phase, during which the comparator signal CMP causes the various nodes of preamplifier 230 and latch 240 to be connected to the reset voltage Vcm. In addition, the comparator signal CMP causes reservoir capacitor 210 to be connected across preamplifier 230 during the comparison phase, during which the comparator signal CMP causes reset switches 252, 254, and 256 to be open.

In some embodiments, the reset voltage Vcm is equal or substantially equal to power supply voltage Vdd/2. In some embodiments, reset switches 252 are configured to selectively connect nodes of preamplifier 230 and latch 240 to a different reset voltage. For example, reset switches 252 may be configured to selectively connect the nodes of preamplifier 230 and latch 240 to the ground voltage. In some embodiments, reset switches 256 are configured to selectively connect nodes of preamplifier 230 and latch 240 to a different reset voltage. For example, reset switches 256 may be configured to selectively connect the nodes of preamplifier 230 and latch 240 to the power supply voltage Vdd.

Preamplifier 230 includes P type transistors 232 and 234, and N type transistors 236 and 238. In some embodiments, latch comparator 200 also includes a reset switch configured to selectively connect the nodes shared by the sources of P type transistors 232 and 234 to the reset voltage Vcm, where the reset switch is controlled by comparator signal CMP, as discussed above with reference to reset switches 252, 254, and 256. In some embodiments, latch comparator 200 also includes a reset switch configured to selectively connect the nodes shared by the sources of N type transistors 236 and 238 to the reset voltage Vem, where the reset switch is controlled by comparator signal CMP, as discussed above with reference to reset switches 252, 254, and 256.

P type transistor 232 and N type transistor 236 receive positive input voltage Vinp. In addition, P type transistor 234 and N type transistor 238 receive negative input voltage Vinn, where the voltage difference between positive input voltage Vinp and negative input voltage Vinn form a differential input voltage to be amplified by latch comparator 200.

Latch 240 includes P type transistors 242 and 244, and N type transistors 246 and 248. P type transistors 232 and 234 of preamplifier 230 are respectively connected to P type transistors 242 and 244 of latch 240. In addition, N type transistors 236 and 238 of preamplifier 230 are respectively connected to N type transistors 246 and 248 of latch 240.

During the comparison phase, the reservoir capacitor 210 is connected across preamplifier 230 and the reset switches 252, 254, and 256 are open. As a result, P type transistors 232 and 234 source a differential current to latch 240. In addition, during the comparison phase, N type transistors 236 and 238 sink a differential current from latch 240.

Because the transistors of latch 240 provide a positive feedback load to preamplifier 230, the differential currents provided to latch 240 from preamplifier 230 cause latch 240 to generate a differential output voltage across output notes Voutp and Voutn having a magnitude approximately equal to power supply voltage Vdd. In addition, the polarity of the differential output voltage is determined by the polarity of the differential currents of preamplifier 230. Accordingly, the differential output voltage generated by latch 240 has a magnitude approximately equal to power supply voltage Vdd, and a sign corresponding with the differential input voltage formed by the voltage difference between positive input voltage Vinp and negative input voltage Vinn. In the illustrated embodiment, the positive feedback load includes cross coupled inverters formed by the illustrated transistors of latch 240.

In some embodiments, latch comparator is controlled by or includes a controller configured to generate the comparator signal CMP.

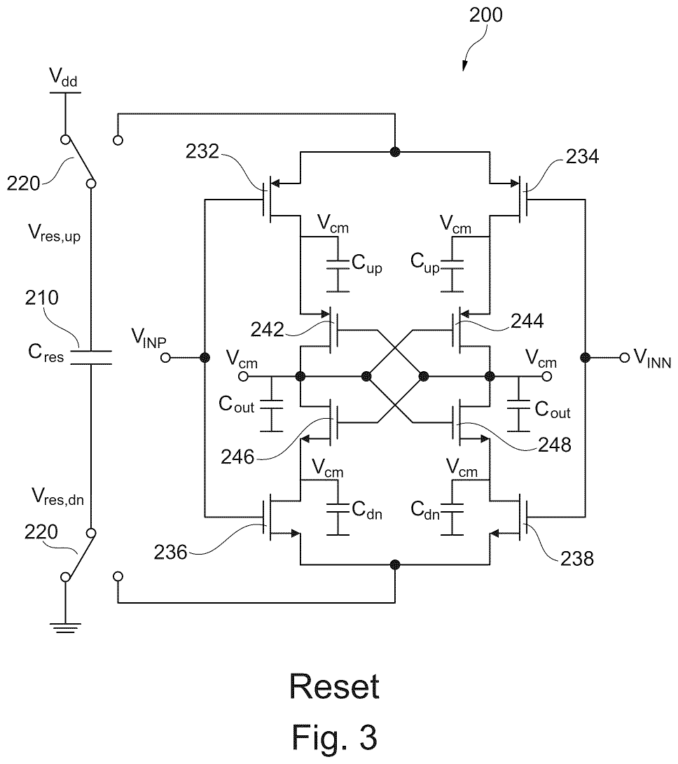

FIG. 3 is a schematic circuit diagram of latch comparator 200 in a reset phase according to some embodiments.

During the reset phase, the comparator signal CMP causes the reservoir capacitor switches 220 to connect reservoir capacitor 210 across power supply voltages Vdd and ground. In addition, during the reset phase, the comparator signal CMP causes the reset switches (not shown for clarity) to be closed. As a result, in the illustrated embodiment, various nodes of latch comparator 200 are set to reset voltage Vcm.

In some embodiments, the reset voltage Vcm is equal or substantially equal to power supply voltage Vdd/2. In some embodiments, some reset switches are configured to selectively connect nodes shared by the P transistors 232, 234, 242, and 244 of preamplifier 230 and latch 240 to a different reset voltage, such as the ground voltage. In some embodiments, some reset switches are configured to selectively connect nodes shared by the N transistors 236, 238, 246, and 248 of preamplifier 230 and latch 240 to a different reset voltage, such as the power supply Vdd voltage.

In some embodiments, latch comparator 200 may be considered to function such that, during the comparison phase, the latch comparator operates with three sub-phases: an integration sub-phase, a propagation sub-phase, and a regeneration sub-phase. While the following discussion generally addresses each sub-phase as being distinct, in some embodiments, transitions between sub-phases are gradual, such that two or all three sub-phases at least partially overlap in time.

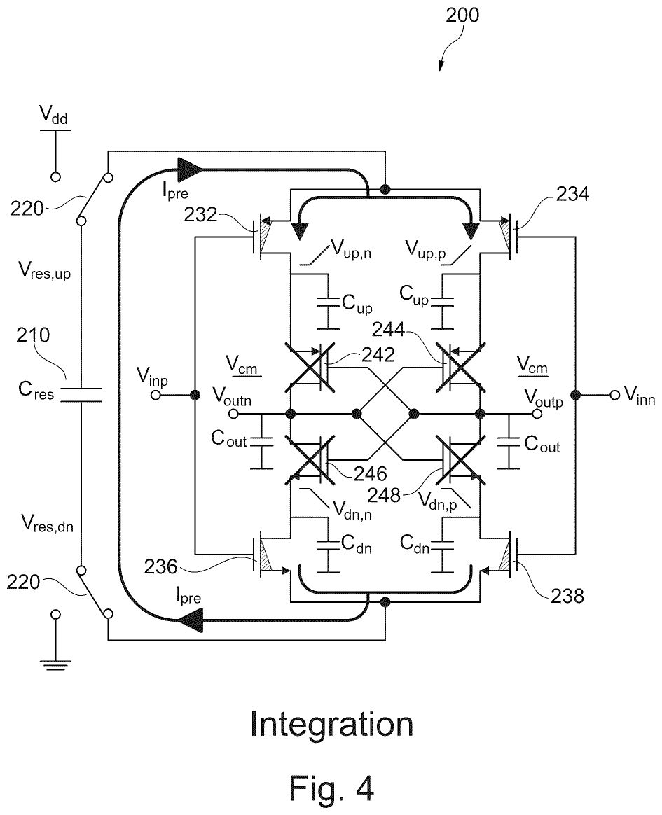

FIG. 4 is a schematic circuit diagram of latch comparator 200 during an integration phase of the comparison phase, according to some embodiments.

During the integration phase, the reservoir capacitor 210, having been previously charged to Vdd during the reset phase, is connected across the preamplifier and latch transistors. As a result, the first and second complementary input pairs respectively formed by P type transistors 232 and 234 and by N type transistors 236 and 238 are turned on and integrate the differential input signal at input nodes Vinp and Vinn across the differential nodes V_{up,p} and V_{up,n} and across the differential nodes V_{dn,p} and V_{dn,n}, where V_{dn,d}=V_{dn,p}−V_{dn,n} and V_{up,d}=V_{up,p}−V_{up,n}, as illustrated. At the end of the integration phase, which has a duration Tint, the input differential signal is amplified as or approximately as:

$${V}_{dn , d} = \frac{2}{{C}_{dn}} {\int }_{0}^{{T}_{int}} \frac{{g}_{m 1}}{2} {V}_{in , d} dt = \frac{{g}_{m 1} {T}_{int}}{{C}_{dn}} {V}_{in , d}$$

$${V}_{up , d} = \frac{2}{{C}_{up}} {\int }_{0}^{{T}_{int}} \frac{{g}_{m 2}}{2} {V}_{in , d} dt = \frac{{g}_{m 2} {T}_{int}}{{C}_{up}} {V}_{in , d}$$

where gₘ₁, gₘ₂ are the transconductances of P type transistors 232 and 234, and N type transistors 236 and 238, respectively, and where capacitances Can, Cup are the lumped capacitances on the V_{dn,p} and V_{dn,n}, and V_{up,p} and V_{up,n} nodes, respectively.

While the signal being integrated, as illustrated, the common-mode current/pre moves charge from the lower voltage nodes (V_{dn,p} and V_{dn,n}) to the upper nodes (V_{up,p} and V_{up,n}) respectively producing a decrease and increase of their common-mode voltages V_{dn,cm} and V_{up,cm}. The integration phase ends when the embedded cross-coupled inverter pair formed by transistors 242, 244, 246, and 248 turn on, that is, for example, when any of transistors 242, 244, 246, and 248 turn on.

For example, one or both of transistors 242 and 244 may turn on when V_{up,cm}=V_{cm}+V_{T242}, where V_{T242} is the threshold voltage of transistors 242 and 244. In addition, one or both of transistors 246 and 248 may turn on when V_{dn,cm}=V_{cm}−V_{T246}, where V_{T246} is the threshold voltage of transistors 246 and 248. In some embodiments, the capacitance and threshold voltage for the two pairs are the same or approximately the same, and the integration phase has a duration Tint, where:

$${T}_{int} = \frac{{C}_{dn / up} {V}_{T 242}}{{I}_{pre}} .$$

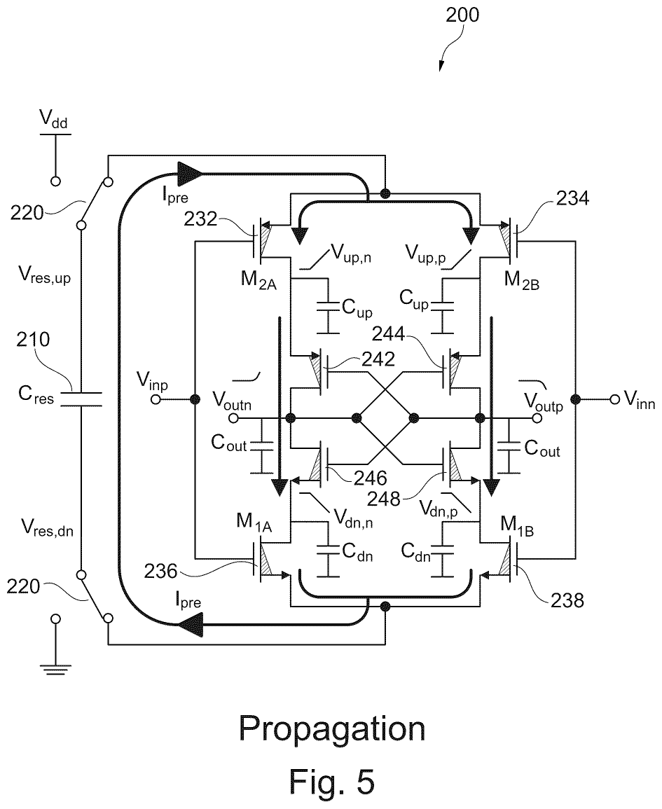

FIG. 5 is a schematic circuit diagram of latch comparator 200 during a propagation phase of the comparison phase according to some embodiments.

During the propagation phase, the cross-coupled inverters formed by transistors 242, 244, 246, and 248 turn on and provide regeneration of the signal, and the differential output signal V_{out,d} begins to transition. For example, both cross-coupled pairs may turn on, and:

$${V}_{out , d} = \frac{( {g}_{m 1} + {g}_{m 2} ) {V}_{in , d}}{s [ {C}_{out} - ( {C}_{dn} + {C}_{up} ) ]} \cdot \frac{1}{1 + s \frac{{C}_{out} ( {C}_{dn} + {C}_{up} )}{{C}_{out} - ( {C}_{dn} + {C}_{up} )} / ( {g}_{m 3} + {g}_{m 4} )} ,$$

where gm3 is the transconductance of transistors 246 and 248, where gm4 is the transconductance of transistors 242 and 244, and where Cout is the output capacitance at each of nodes Voutp and Voutn.

When Cout is less than Cdn+Cup, for example, because of noise considerations, a local positive feedback is designed in the circuit that begins the regeneration of the output signal. In some embodiments, the propagation phase is short. Specifically, it may last until the input pairs formed by transistors 232, 234, 236, and 238 enter linear region operation. This happens, for example, when Vdn (common mode)=Vin (common mode)−VT of transistors 236 and Vup (common mode)=Vin (common mode)+VT of transistor 232.

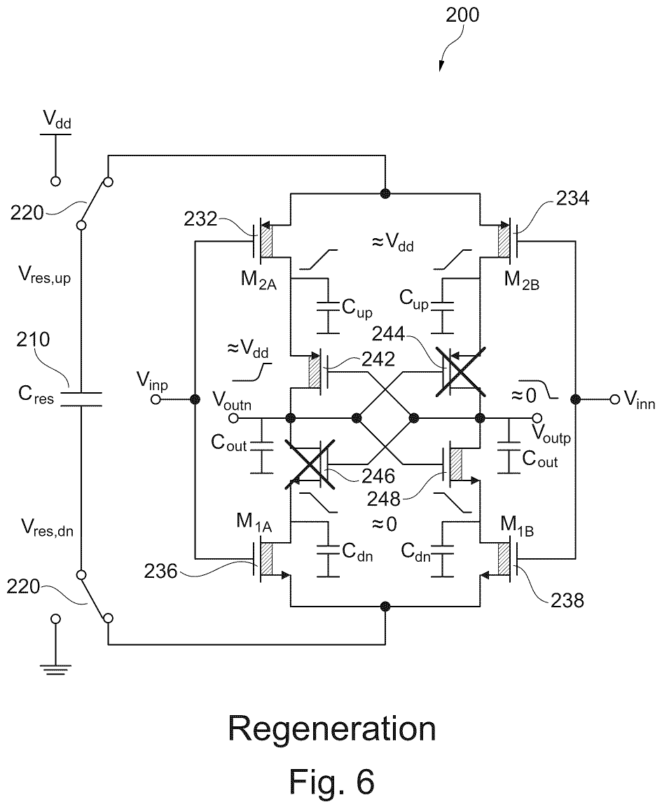

FIG. 6 is a schematic circuit diagram of latch comparator 200 during a regeneration phase of the comparison phase according to some embodiments.

During the regeneration phase, the cross-coupled inverters formed by transistors 242, 244, 246, and 248 are on to fully regenerate the signal, and the differential output signal V_{out,d} transitions to its maximum differential value. As the cross-coupled inverters operate in the linear region, the source voltages of the cross-coupled inverters saturate to the reservoir capacitor 210 voltages, and the common mode voltage of the drains of the transistors 232 and 234 Vup (common mode)≈Vdd, and the common mode voltage of the drains of the transistors 236 and 238 Vdn (common mode)≈0.

Letting Vout,d(o) be the differential output voltage at the beginning of the regeneration phase, then:

$${V}_{out , d} ( t ) = {V}_{out , d} ( 0 ) {e}^{t / τ}$$

where τ=Cout/(gm3+gm4) is the regeneration time constant.

The differential output voltage Vout,d exponentially grows over time until the cross-coupled inverter pair fully latches and saturates the outputs to the reservoir voltages Vres,up and Vres,dn, where the sign or polarity of the differential output voltage Vout,d depends on the and corresponds with the sign of the differential input signal. The regeneration phase may be considered as lasting until the differential output voltage Vout,d reaches a conventionally chosen voltage level, such as Vdd/2.

Latch comparator 200 achieves common-mode insensitivity from the input signal. During the integration phase, the floating power domain causes sum of the current in transistors 232 and 234 to be equal to the sum of the current in transistors 236 and 238. Consequently, the source voltages of the p-type and n-type input pairs shift by the same amount of the input common-mode voltage, hence always biasing the input transistors in the correct operating region (that is, at the same gate-source voltages). This helps to ensure that the comparator performance, which is influenced by the operating point of the input pairs, remains constant with respect to the input common-mode voltage.

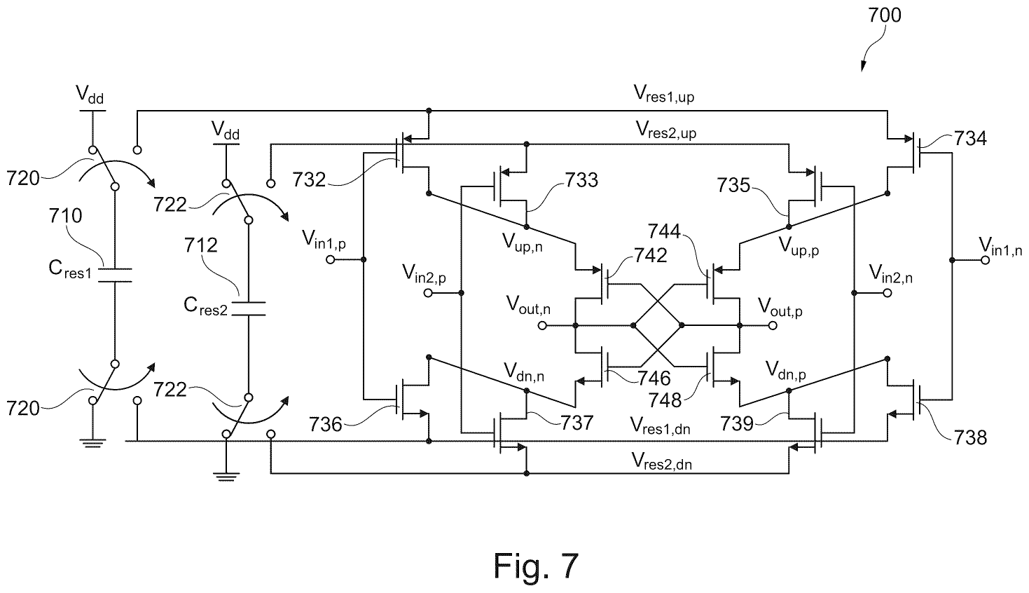

FIG. 7 is a schematic circuit diagram of a latch comparator 700 according to some embodiments. Latch comparator 700 may be used, for example, in a SAR ADC having features similar or identical to SAR ADC 100. In some embodiments, comparators having features similar or identical to latch comparator 700 may be used in a SAR ADC circuit, or in other circuits.

Latch comparator 700 includes reservoir capacitors 710 and 712, reservoir capacitor switches 720 and 722, a first preamplifier including transistors 732, 734, 736, and 738, a second preamplifier including transistors 733, 735, 737, and 739, a latch including transistors cross coupled inverters formed from transistors 742, 744, 746, and 748. In some embodiments, reset switches similar or identical to reset switches 252, 254, and 256 of latch comparator 200 are also included.

Reservoir capacitor 710 is configured to be selectively connected across power supply voltages Vdd and ground by reservoir capacitor switches 720 according to a comparator signal CMP. While reservoir capacitor 710 is connected to power supply voltages Vdd and ground, during a reset phase, reservoir capacitor 710 is charged to power supply voltage Vdd.

Similarly, reservoir capacitor 712 is configured to be selectively connected across power supply voltages Vdd and ground by reservoir capacitor switches 722 according to the comparator signal CMP. While reservoir capacitor 712 is connected to power supply voltages Vdd and ground, during a reset phase, reservoir capacitor 712 is charged to power supply voltage Vdd.

Reservoir capacitor 710 is configured to be selectively connected across the first preamplifier by reservoir capacitor switches 720 according to the comparator signal CMP. While reservoir capacitor 710 is connected across the first preamplifier, during a comparison phase, reservoir capacitor 710 is discharged or partially discharged through the first preamplifier and the latch.

Reservoir capacitor 712 is configured to be selectively connected across the second preamplifier by reservoir capacitor switches 722 according to the comparator signal CMP. While reservoir capacitor 712 is connected across the second preamplifier, during the comparison phase, reservoir capacitor 712 is discharged or partially discharged through the second preamplifier and the latch.

Reset switches may be configured to selectively connect various nodes of the first and second preamplifiers and the latch to a reset voltage V_{cm}. The reset switches may selectively connect and disconnect the nodes of the first and second preamplifiers and the latch to the reset voltage according to comparator signal CMP. The comparator signal CMP causes reservoir capacitors 710 and 712 to be connected to the power supply voltages Vdd and ground during the reset phase, during which the comparator signal CMP causes the various nodes of the first and second preamplifiers and the latch to be connected to the reset voltage V_{cm}. In addition, the comparator signal CMP causes reservoir capacitor 710 to be connected across the first preamplifier and causes reservoir capacitor 712 to be connected across the second preamplifier during the comparison phase, during which the comparator signal CMP causes the reset switches to be open.

In some embodiments, the reset voltage Vem is equal or substantially equal to power supply voltage Vdd/2. In some embodiments, the reset switches are configured to selectively connect nodes of the first and second preamplifiers and the latch to a different reset voltage. For example, the reset switches may be configured to selectively connect the nodes of the first and second preamplifiers and the latch to the ground voltage. In some embodiments, the reset switches are configured to selectively connect nodes of the first and second preamplifiers and the latch to a different reset voltage. For example, the reset switches may be configured to selectively connect the nodes of the first and second preamplifier and the latch to the power supply voltage Vdd.

In some embodiments, latch comparator 700 also includes a reset switch configured to selectively connect the nodes shared by the sources of P type transistors 732, 733, 734, and 735 to a reset voltage, where the reset switch is controlled by comparator signal CMP, as discussed above. In some embodiments, latch comparator 700 also includes a reset switch configured to selectively connect the nodes shared by the sources of N type transistors 736, 737, 738, and 739 to a reset voltage, where the reset switch is controlled by comparator signal CMP, as discussed above.

P type transistor 732 and N type transistor 736 receive first positive input voltage Vin1,p. In addition, P type transistor 734 and N type transistor 738 receive first negative input voltage Vin1,n, where the voltage difference between first positive input voltage Vin1,p and first negative input voltage Vin1,n form a first differential input voltage.

P type transistor 733 and N type transistor 737 receive second positive input voltage Vin2,p. In addition, P type transistor 735 and N type transistor 739 receive second negative input voltage Vin2,n, where the voltage difference between positive second input voltage Vin2,p and second negative input voltage Vin2,n form a second differential input voltage.

A latch includes P type transistors 742 and 744, and N type transistors 746 and 748. P type transistors 732 and 734 of the first preamplifier are respectively connected to P type transistors 742 and 744 of the latch. In addition, N type transistors 736 and 738 of the first preamplifier are respectively connected to N type transistors 746 and 748 of the latch. Furthermore, P type transistors 733 and 735 of the second preamplifier are respectively connected to P type transistors 742 and 744 of the latch. In addition, N type transistors 737 and 739 of the second preamplifier are respectively connected to N type transistors 746 and 748 of the latch.

During the comparison phase, the reservoir capacitor 710 is connected across the first preamplifier, the reservoir capacitor 712 is connected across the second preamplifier, and the reset switches are open. As a result, P type transistors 732 and 734 source a first differential current to the latch, and P type transistors 733 and 735 source a second differential current to the latch. In addition, during the comparison phase, N type transistors 736 and 738 sink a third differential current from the latch, and N type transistors 737 and 739 sink a fourth differential current from the latch.

Because the transistors of the latch provide a positive feedback load to the first and second preamplifiers, the differential currents provided to the latch from first and second preamplifiers cause the latch to generate a differential output voltage across output notes Vout,p and Vout,n having a magnitude approximately equal to power supply voltage Vdd. In addition, the sign of the differential output voltage is determined by the sign of the summed differential currents of first and second preamplifiers. Accordingly, the differential output voltage generated by the latch has a magnitude approximately equal to power supply voltage Vdd, and a sign corresponding with the differential input voltages formed by the voltage differences between first positive input voltage Vin1,p and first negative input voltage Vin1,n, and second positive input voltage Vin2,p and second negative input voltage Vin2,n, as weighted by the transconductances of the first and second preamplifiers. In the illustrated embodiment, the positive feedback load includes cross coupled inverters formed by the illustrated transistors of the latch.

In some embodiments, latch comparator 700 is controlled by or includes a controller configured to generate the comparator signal CMP.

Latch comparator 700 operates according to principles similar or identical to those discussed above with reference to latch comparator 200. For example, in some embodiments, latch comparator 700 operates in a reset phase and in a comparison phase. In some embodiments, latch comparator 700 may be considered to function such that, during the comparison phase, the latch comparator 700 operates with three sub-phases: an integration sub-phase, a propagation sub-phase, and a regeneration sub-phase, each sub-phase having characteristics similar or identical to those discussed above with reference to latch comparator 200.

During the comparison phase, the effective differential current Id to the latch in the circuit is:

$${I}_{d} = {G}_{{m}_{1}} {V}_{in 1 , d} + {G}_{{m}_{2}} {V}_{in 2 , d}$$

where V_{in1,d} is the first differential input of the comparator, and V_{in2,d} is the second differential input of the comparator, where Gₘ_{₁}, Gₘ_{₂} are the effective transconductances associated with the transistors receiving the first and second inputs, respectively.

The comparator output is then determined by the sign of the differential current l_{d}.

In some embodiments, Gₘ_{₁} is equal or substantially equal to Gₘ_{₂}.

In some embodiments, Gₘ_{₁} is not equal to Gₘ_{₂}. For example, a ratio Gₘ_{₁}/Gₘ_{₂} may be achieved by the designer through a size ratio of transistors 732, 734, 736, and 738 to transistors 733, 735, 737, and 739. For example, in some embodiments:

$$\frac{{G}_{{m}_{1}}}{{G}_{{m}_{2}}} = \frac{{( w / L )}_{1}}{{( w / L )}_{2}}$$

where (w/L)₁, and (w/L)₂ respectively indicate width to length aspect ratio values for the transistors receiving the first and second inputs.

Because latch comparator 700 has a complementary input architecture (both P and N type transistors), four drain connections are used. In the illustrated embodiment, the drains of the P type transistors are connected to the shared nodes V_{up,p} and V_{up,n}, and the drains of the N type transistors are connected to nodes V_{dn,p} and V_{dn,n}. Furthermore, to enhance the input common-mode insensitivity of the latch comparator 700 for both inputs, each of the first and second inputs is powered by a different reservoir capacitor.

Referring to FIG. 7, the nodes of voltages V_{res1,up}, V_{res1,dn} are selectively connectable to reservoir capacitor 710, and the nodes of voltages V_{res2,up}, V_{res2,dn} are selectively connectable to reservoir capacitor 712.

In some embodiments, to improve matching between the first and second inputs, reservoir capacitors 710 are sized to have a capacitance ratio equal to the transconductance ratio Gₘ_{₁}/Gₘ_{₂}. In some embodiments, to improve matching between the first and second inputs, the switches 720 and 722 are sized to have a transconductance ratio equal to the transconductance ratio Gₘ_{₁}/Gₘ_{₂}.

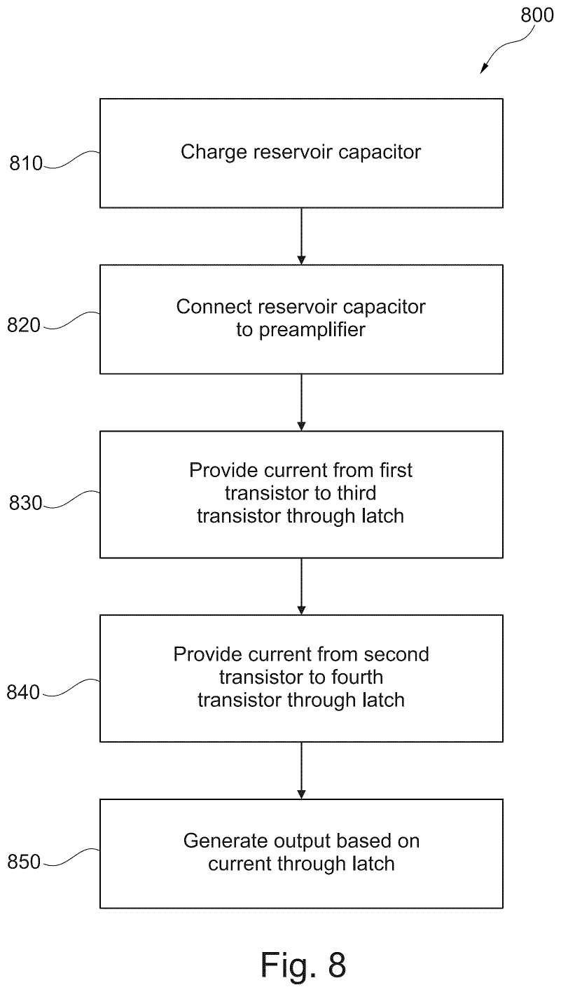

FIG. 8 is a flowchart of a method of operating a latch comparator according to some embodiments, where the latch comparator includes at least a latch and one or more preamplifiers, each of the preamplifiers including at least first, second, third, and fourth transistors. The method may be performed on or by latch comparator 200 or latch comparator 700.

At block 810, one or more reservoir capacitors are charged. For example, one or more power switches for each of the reservoir capacitors to be charged may be switched to connect the reservoir capacitor to power and ground nodes. In addition, in response to the reservoir capacitors being connected to the power and ground nodes, the reservoir capacitors are charged to voltage differences corresponding with the voltage difference between the power and ground nodes. In some embodiments, the one or more reservoir capacitors are charged according to principles which are similar or identical to those discussed above with reference to FIG. 3.

At block 820, each of the charged reservoir capacitors is connected to a preamplifier of the latch comparator. For example, the power switches for each of the reservoir capacitors may be opened such that the reservoir capacitors are no longer connected to the power and ground nodes, and one or more preamplifiers switches for each of the reservoir capacitors may be closed such that each of the reservoir capacitors are connected across one of the one or more preamplifiers. In some embodiments, each of the charged reservoir capacitors is connected to a preamplifier according to principles similar or identical to those discussed above with reference to FIG. 4.

At block 830, each of the one or more preamplifiers receives a differential input voltage having first and second input voltages, where, in the case of multiple preamplifiers, the differential input voltages are not necessarily the same. The first input voltage is received by at least one of the first and third transistors of each preamplifier, and, in response to the received first input voltage, the first transistor sources current to the latch and the third transistor sinks current from the latch. Accordingly, current flows from the first transistor to the third transistor through the latch. In some embodiments, the first and third transistors of each preamplifier operate according to principles which are similar or identical to those discussed above with reference to FIGS. 4-6.

At block 840, each of the one or more preamplifiers receives the differential input voltage having the first and second input voltages. The second input voltage is received by at least one of the second and fourth transistors of each preamplifier, and, in response to the received second input voltage, the second transistor sources current to the latch and the fourth transistor sinks current from the latch. Accordingly, current flows from the second transistor to the fourth transistor through the latch. In some embodiments, the second and fourth transistors of each preamplifier operate according to principles which are similar or identical to those discussed above with reference to FIGS. 4-6.

At block 850, the latch generates a differential output voltage in response to the current flowing therethrough. For example, the differential output voltage may have a magnitude approximately equal to, or based on, the voltage to which the one or more reservoir capacitors have been charged, and a sign corresponding with the one or more differential input voltages received by the one or more preamplifiers. In some embodiments, the one or more preamplifiers and the latch operate according to principles which are similar or identical to those discussed above with reference to FIGS. 4-6.

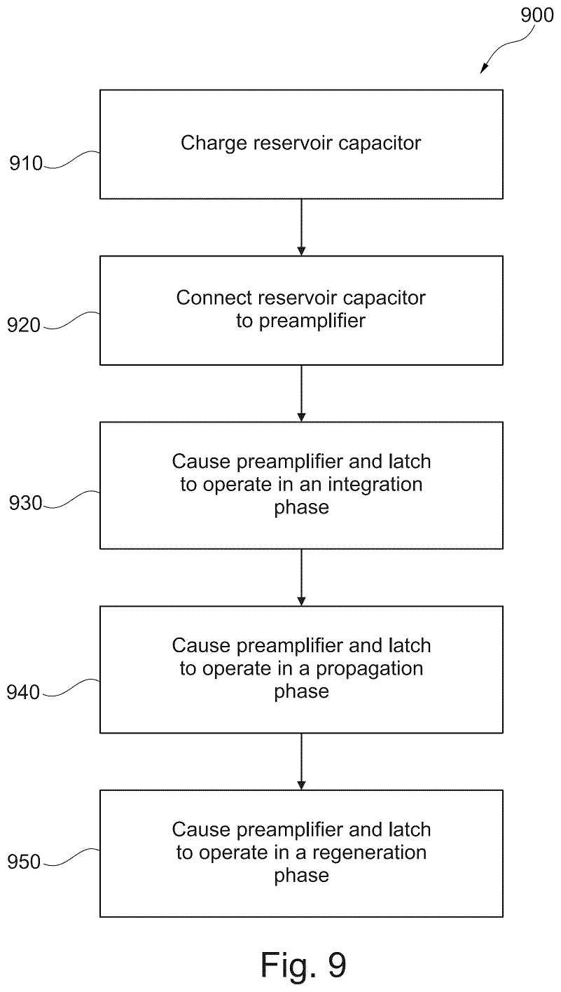

FIG. 9 is a flowchart of a method of operating a latch comparator according to some embodiments, where the latch comparator includes at least a latch and one or more preamplifiers, each of the preamplifiers including at least first, second, third, and fourth transistors. The method may be performed on or by latch comparator 200 or latch comparator 700.

At block 910, one or more reservoir capacitors are charged. For example, one or more power switches for each of the reservoir capacitors to be charged may be switched to connect the reservoir capacitor to power and ground nodes. In addition, in response to the reservoir capacitors being connected to the power and ground nodes, the reservoir capacitors are charged to voltage differences corresponding with the voltage difference between the power and ground nodes. In some embodiments, the one or more reservoir capacitors are charged according to principles which are similar or identical to those discussed above with reference to FIG. 3.

At block 920, each of the charged reservoir capacitors is connected to a preamplifier of the latch comparator. For example, the power switches for each of the reservoir capacitors may be opened such that the reservoir capacitors are no longer connected to the power and ground nodes, and one or more preamplifiers switches for each of the reservoir capacitors may be closed such that each of the reservoir capacitors are connected across one of the one or more preamplifiers. In some embodiments, each of the charged reservoir capacitors is connected to a preamplifier according to principles similar or identical to those discussed above with reference to FIG. 4.

At block 930, the one or more preamplifiers and the latch operate in an integration phase. In some embodiments, the integration phase has characteristics which are similar or identical to those discussed above with reference to FIG. 4.

At block 940, the one or more preamplifiers and the latch operate in a propagation phase. In some embodiments, the propagation phase has characteristics which are similar or identical to those discussed above with reference to FIG. 5.

At block 950, the one or more preamplifiers and the latch operate in a regeneration phase. In some embodiments, the regeneration phase has characteristics which are similar or identical to those discussed above with reference to FIG. 6.

Embodiments of the present invention are summarized here. Other embodiments can also be understood from the entirety of the specification and the claims filed herein.

One embodiment is a latch comparator, including a first reservoir capacitor; a preamplifier including first and second transistors respectively connected to first and second inputs, the first and second transistors selectably connectable to a first terminal of the first reservoir capacitor, and third and fourth transistors respectively connected to the first and second inputs, the third and fourth transistors selectably connectable to a second terminal of the first reservoir capacitor; and a latch, including a first portion serially connected between the first and third transistors and connected to a first output, and a second portion serially connected between the second and fourth transistors and connected to a second output. In some embodiments, the first reservoir capacitor is selectably connectable to a voltage source. In some embodiments, the first, second, third, and fourth transistors are each selectably connectable to one of one or more reset voltages. In some embodiments, the first output and the second output are selectably connectable to a common mode voltage. In some embodiments, the first portion of the latch includes a first inverter, where the second portion of the latch includes a second inverter, and where the first and second inverters are cross-coupled. In some embodiments, the latch comparator further includes a controller configured to during a reset phase, charge the first reservoir capacitor to a first voltage; and during an comparison phase, connect the first reservoir capacitor to the first, second, third, and fourth transistors, where the first, second, third, and fourth transistors, and the latch are configured to float during the comparison phase. In some embodiments, the controller is further configured to during the reset phase, connect each of the first, second, third, and fourth transistors, and the latch to one of one or more reset voltages; and during the comparison phase, disconnect the first, second, third, and fourth transistors, and the latch from the reset voltage connected thereto in the reset phase. Some embodiments further include fifth and sixth transistors respectively connected to third and fourth inputs, the fifth and sixth transistors selectably connectable to a first terminal of a second reservoir capacitor; and seventh and eighth transistors respectively connected to the third and fourth inputs, the seventh and eighth transistors selectably connectable to a second terminal of the second reservoir capacitor, where the first portion of the latch is serially connected between the fifth and seventh transistors and connected to a third output, and where the second portion of the latch is serially connected between the sixth and eighth transistors and connected to a fourth output. In some embodiments, the fifth and sixth transistors each have aspect ratios that are scaled by a first factor with respect to an aspect ratio of the first and second transistors, and where the second reservoir capacitor has an area scaled by the first factor with respect to an area of the first reservoir capacitor.

Another embodiment is a data converter, including the latch comparator of claim 1; a sample and hold circuit connected to the first and second inputs of the latch comparator; a capacitive digital to analog converter (DAC) connected to the sample and hold circuit; and a successive approximation register (SAR) logic circuit connected to the capacitive DAC and to the first and second outputs of the latch comparator. Some embodiments further include a controller configured to during a reset phase, charge the reservoir capacitor to a first voltage; and during a comparison phase, connect the reservoir capacitor to the first, second, third, and fourth transistors, where the first, second, third, and fourth transistors, and the latch are configured to float during the comparison phase. In some embodiments, the controller is further configured to during the reset phase, connect each of the first, second, third, and fourth transistors, and the latch to one of one or more reset voltages; and during the comparison phase, disconnect the first, second, third, and fourth transistors, and the latch from the reset voltage connected thereto in the reset phase.

Another embodiment is a latch comparator, including a reservoir capacitor; first and second transistors respectively connected to first and second inputs, the first and second transistors selectably connectable to a first terminal of the reservoir capacitor; third and fourth transistors respectively connected to the first and second inputs, the third and fourth transistors selectably connectable to a second terminal of the reservoir capacitor; fifth and sixth transistors serially connected between the first and third transistors and connected to a first output; and seventh and eighth transistors serially connected between the second and fourth transistors and connected to a second output. In some embodiments, the reservoir capacitor is selectably connectable to a voltage source. In some embodiments, the first, second, third, and fourth transistors are selectably connectable to a common mode voltage by ninth, tenth, eleventh, and twelfth transistors, respectively. In some embodiments, the first and second outputs are selectably connectable to a common mode voltage by thirteenth and fourteenth transistors, respectively. In some embodiments, the fifth and sixth transistors form a first inverter, where the seventh and eighth transistors form a second inverter, and where the first and second inverters are cross-coupled. Some embodiments further include ninth and tenth transistors respectively connected to third and fourth inputs, the ninth and tenth transistors selectably connectable to a first terminal of a second reservoir capacitor; and eleventh and twelfth transistors respectively connected to the third and fourth inputs, the eleventh and twelfth transistors selectably connectable to a second terminal of the second reservoir capacitor, where the fifth and sixth transistors are serially connected between the ninth and eleventh transistors and are connected to a third output, and where the seventh and eighth transistors are serially connected between the tenth and twelfth transistors and are connected to a fourth output.

Another embodiment is a method of operating a latch comparator, the method including during a reset phase, charging a reservoir capacitor to a first voltage; and during an comparison phase, connecting the reservoir capacitor to first, second, third, and fourth transistors, where the first, second, third, and fourth transistors, and a latch are configured to float during the comparison phase, and where at least one of the first transistor is configured to provide current to the third transistor through the latch, where the latch generates a differential output voltage, or the second transistor is configured to provide current to the fourth transistor through the latch, where the latch generates a differential output voltage. Some embodiments further include during the reset phase, connecting each of the first, second, third, and fourth transistors, and the latch to one of one or more reset voltages; and during the comparison phase, disconnecting the first, second, third, and fourth transistors, and the latch from the reset voltage connected thereto in the reset phase.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A latch comparator, comprising:
a first reservoir capacitor;
a preamplifier comprising:
first and second transistors respectively connected to first and second inputs, the first and second transistors selectably connectable to a first terminal of the first reservoir capacitor, and
third and fourth transistors respectively connected to the first and second inputs, the third and fourth transistors selectably connectable to a second terminal of the first reservoir capacitor; and
a latch, comprising:
a first portion serially connected between the first and third transistors and connected to a first output, and
a second portion serially connected between the second and fourth transistors and connected to a second output.

2. The latch comparator of claim 1, wherein the first reservoir capacitor is selectably connectable to a voltage source.

3. The latch comparator of claim 1, wherein the first, second, third, and fourth transistors are each selectably connectable to one of one or more reset voltages.

4. The latch comparator of claim 1, wherein the first output and the second output are selectably connectable to a common mode voltage.

5. The latch comparator of claim 1, wherein the first portion of the latch comprises a first inverter, wherein the second portion of the latch comprises a second inverter, and wherein the first and second inverters are cross-coupled.

6. The latch comparator of claim 1, further comprising a controller configured to:
during a reset phase, charge the first reservoir capacitor to a first voltage; and
during a comparison phase, connect the first reservoir capacitor to the first, second, third, and fourth transistors, wherein the first, second, third, and fourth transistors, and the latch are configured to float during the comparison phase.

7. The latch comparator of claim 6, wherein the controller is further configured to:
during the reset phase, connect each of the first, second, third, and fourth transistors, and the latch to one of one or more reset voltages; and
during the comparison phase, disconnect the first, second, third, and fourth transistors, and the latch from the reset voltage connected thereto in the reset phase.

8. The latch comparator of claim 1, further comprising:
fifth and sixth transistors respectively connected to third and fourth inputs, the fifth and sixth transistors selectably connectable to a first terminal of a second reservoir capacitor; and
seventh and eighth transistors respectively connected to the third and fourth inputs, the seventh and eighth transistors selectably connectable to a second terminal of the second reservoir capacitor,
wherein the first portion of the latch is serially connected between the fifth and seventh transistors and connected to a third output, and
wherein the second portion of the latch is serially connected between the sixth and eighth transistors and connected to a fourth output.

9. The latch comparator of claim 8, wherein the fifth and sixth transistors each have aspect ratios that are scaled by a first factor with respect to an aspect ratio of the first and second transistors, and wherein the second reservoir capacitor has an area scaled by the first factor with respect to an area of the first reservoir capacitor.

10. A data converter, comprising:
the latch comparator of claim 1;
a sample and hold circuit connected to the first and second inputs of the latch comparator;
a capacitive digital to analog converter (DAC) connected to the sample and hold circuit; and
a successive approximation register (SAR) logic circuit connected to the capacitive DAC and to the first and second outputs of the latch comparator.

11. The data converter of claim 10, further comprising a controller configured to:
during a reset phase, charge the reservoir capacitor to a first voltage; and
during a comparison phase, connect the reservoir capacitor to the first, second, third, and fourth transistors, wherein the first, second, third, and fourth transistors, and the latch are configured to float during the comparison phase.

12. The data converter of claim 11, wherein the controller is further configured to:
during the reset phase, connect each of the first, second, third, and fourth transistors, and the latch to one of one or more reset voltages; and
during the comparison phase, disconnect the first, second, third, and fourth transistors, and the latch from the reset voltage connected thereto in the reset phase.

13. A latch comparator, comprising:
a reservoir capacitor;
first and second transistors respectively connected to first and second inputs, the first and second transistors selectably connectable to a first terminal of the reservoir capacitor;
third and fourth transistors respectively connected to the first and second inputs, the third and fourth transistors selectably connectable to a second terminal of the reservoir capacitor;
fifth and sixth transistors serially connected between the first and third transistors and connected to a first output; and
seventh and eighth transistors serially connected between the second and fourth transistors and connected to a second output.

14. The latch comparator of claim 13, wherein the reservoir capacitor is selectably connectable to a voltage source.

15. The latch comparator of claim 13, wherein the first, second, third, and fourth transistors are selectably connectable to a common mode voltage by ninth, tenth, eleventh, and twelfth transistors, respectively.

16. The latch comparator of claim 13, wherein the first and second outputs are selectably connectable to a common mode voltage by thirteenth and fourteenth transistors, respectively.

17. The latch comparator of claim 13, wherein the fifth and sixth transistors form a first inverter, wherein the seventh and eighth transistors form a second inverter, and wherein the first and second inverters are cross-coupled.

18. The latch comparator of claim 13, further comprising:
ninth and tenth transistors respectively connected to third and fourth inputs, the ninth and tenth transistors selectably connectable to a first terminal of a second reservoir capacitor; and
eleventh and twelfth transistors respectively connected to the third and fourth inputs, the eleventh and twelfth transistors selectably connectable to a second terminal of the second reservoir capacitor,
wherein the fifth and sixth transistors are serially connected between the ninth and eleventh transistors and are connected to a third output, and
wherein the seventh and eighth transistors are serially connected between the tenth and twelfth transistors and are connected to a fourth output.

19. A method of operating a latch comparator, the method comprising:
during a reset phase, charging a reservoir capacitor to a first voltage; and
during a comparison phase, connecting the reservoir capacitor to first, second, third, and fourth transistors, wherein the first, second, third, and fourth transistors, and a latch are configured to float during the comparison phase, and wherein at least one of:
the first transistor is configured to provide current to the third transistor through the latch, wherein the latch generates a differential output voltage, or
the second transistor is configured to provide current to the fourth transistor through the latch, wherein the latch generates a differential output voltage.

20. The method of claim 19, further comprising:
during the reset phase, connecting each of the first, second, third, and fourth transistors, and the latch to one of one or more reset voltages; and
during the comparison phase, disconnecting the first, second, third, and fourth transistors, and the latch from the reset voltage connected thereto in the reset phase.
